(19) United States
(12) Patent Application Publication
(10) Pub. No.: US 2008/0296741 A1
(43) Pub. Date: Dec. 4, 2008

(54) SEMICONDUCTOR DEVICE

(75) Inventors: Hisayuki Saeki, Itami-shi (JP); Masahiro Totsuka, Tokyo (JP); Tomoki Oku, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/871,230

(22) Filed: Oct. 12, 2007

(30) Foreign Application Priority Data
May 30, 2007 (JP) 2007-143890

(51) Int. Cl. H01L 23/58

(52) U.S. Cl. 257/637; 257/E23.002

(57) ABSTRACT

Passivation films including first and second layers (first passivation film) are formed on a GaAs substrate (semiconductor substrate). A SiN film (second passivation film) is formed on the passivation films as a top layer passivation film by a catalytic chemical vapor deposition. The SiN film formed by catalytic chemical vapor deposition has a lower degree of hygroscopicity than that of a conventional SiN film formed by plasma chemical vapor deposition.

### BACKGROUND OF THE INVENTION

1. Field of the Invention

The present invention relates to a semiconductor device with a passivation film formed on a semiconductor substrate, and more particularly, to a semiconductor device capable of improving an anti-moisture property thereof.

2. Background Art

FIG. 13 is a cross-sectional view showing a conventional semiconductor device. A semiconductor element having a drain electrode 12, a source electrode 13 and a gate electrode 14 or the like is formed on a GaAs substrate 11. Passivation films 15, 16 are formed on the GaAs substrate 11 so as to cover this semiconductor element. Wiring metals 18 are formed so as to penetrate the passivation films 15, 16. A SiN film 23 of 3000 Å is formed on the passivation films 15, 16 as a top layer passivation film using a plasma chemical vapor deposition method.

Furthermore, a method of forming a first layer passivation film which contacts the semiconductor using a catalytic chemical vapor deposition (Cat-CVD) method is proposed (e.g., see [Patent Document 1] Japanese Patent Laid-Open No. 10-209151, [Patent Document 2] Japanese Patent Laid-Open No. 2006-302999, [Patent Document 3] Japanese Patent Laid-Open No. 2002-217193, [Patent Document 4] Japanese Patent Laid-Open No. 2006-269673).

### SUMMARY OF THE INVENTION

However, Patent Document 1 or the like has no description on forming passivation films of second and subsequent layers using a catalytic chemical vapor deposition method. That is, passivation films of the second and subsequent layers are conventionally formed using a plasma chemical vapor deposition method. However, since the SiN film formed using the plasma chemical vapor deposition method has a high degree of hygroscopicity, there is a problem that an anti-moisture property thereof declines.

The present invention has been implemented to solve the above described problem and it is an object of the present invention to obtain a semiconductor device capable of improving the anti-moisture property thereof.

According to one aspect of the present invention, a semiconductor device comprises a semiconductor substrate; a first passivation film which covers a top surface of the semiconductor substrate; and a second passivation film formed on the first passivation film using a catalytic chemical vapor deposition method.

Other and further objects, features and advantages of the invention will appear more fully from the following description.

### BRIEF DESCRIPTION OF THE DRAWINGS

FIGS. 1-5 are sectional views for explaining a method of manufacturing a semiconductor device according to First Embodiment of the present invention.

FIG. 6 shows a spectrum of a semiconductor device using a P-CVD film measured using an FTIR before and after a PCT test.

FIG. 7 shows a spectrum of a semiconductor device using a Cat-CVD film measured using an FTIR before and after a PCT test.

FIG. 8 shows the amount of oxidation measured after a PCT test on a semiconductor device using a P-CVD film and a semiconductor device using a Cat-CVD film.

FIG. 9 is a cross-sectional view showing a semiconductor device according to Second Embodiment of the present invention.

FIG. 10 is a cross-sectional view showing a semiconductor device according to Third Embodiment of the present invention.

FIG. 11 is a cross-sectional view showing a semiconductor device according to Fourth Embodiment of the present invention.

FIG. 12 is a cross-sectional view showing a semiconductor device according to Fifth Embodiment of the present invention.

FIG. 13 is a cross-sectional view showing a conventional semiconductor device.

### DETAILED DESCRIPTION OF THE PREFERRED EMBODIMENTS

### First Embodiment

Hereinafterr the method of manufacturing a semiconductor device according to First Embodiment of the present invention will be explained using drawings.

First, as shown in FIG. 1, a semiconductor element having a drain electrode 12, a source electrode 13 and a gate electrode 14 or the like is formed on a GaAs substrate 11 (semiconductor substrate).

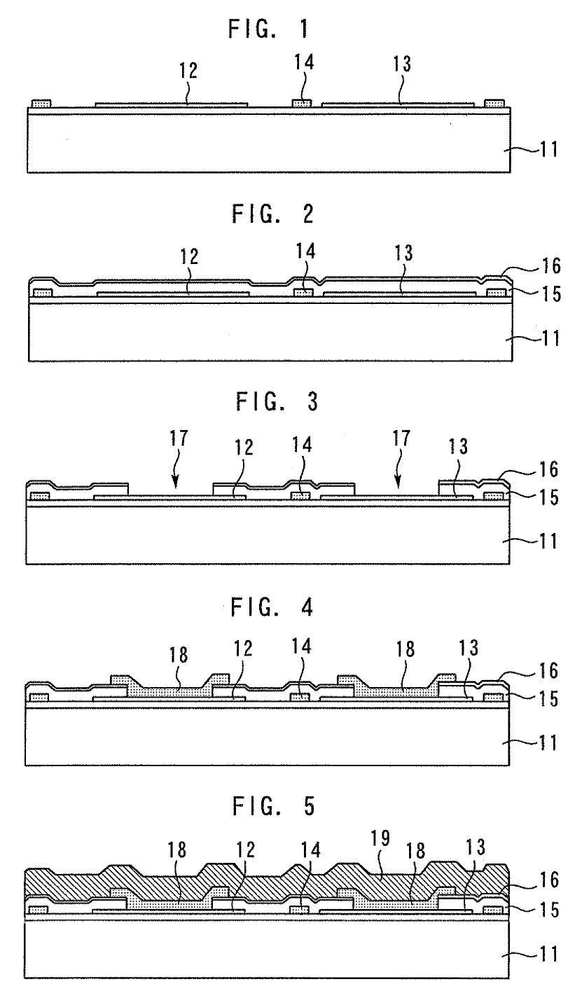

Next, as shown in FIG. 2, passivation films of first and second layers 15, 16 (first passivation film) are formed on the GaAs substrate 11 so as to cover this semiconductor element.

Next, as shown in FIG. 3, apertures 17 are formed in the passivation films 15, 16 so that parts of the drain electrode 12 and the source electrode 13 are exposed. As shown in FIG. 4, after wiring metals 18 are embedded in the apertures 17, the wiring metals 18 are patterned.

Next, as shown in FIG. 5, a SiN film 19 (second passivation film) of 3000 Å is formed on the passivation films 15, 16 as a top layer passivation film using a catalytic chemical vapor deposition method. Here, the catalytic chemical vapor deposition (Cat-CVD) method is a method of forming a film whereby a source gas is made to have contact with a heated catalyst, broken down using catalytic cracking reaction on the surface thereof and the seed of cracking is transported to a substrate kept to a low temperature to form a film. A semiconductor device according to First Embodiment of the present invention is manufactured through the above described steps.

The semiconductor device according to First Embodiment of the present invention has the GaAs substrate 11 (semiconductor substrate), the passivation films 15, 16 (first passivation film) that cover the surface of the GaAs substrate 11 and the SiN film 19 (second passivation film) formed on the passivation films 15, 16 using a catalytic chemical vapor deposition method.

The SiN film (hereinafter, referred to as a “Cat-CVD film”) formed using catalytic chemical vapor deposition has an etching rate of 10 Å/min in buffered fluorinated acid (BHF), which is smaller than 1000 Å/min of the SiN film formed using plasma chemical vapor deposition (hereinafter, referred to as a “P-CVD film”). In this way, the Cat-CVD film is a compact SiN film and has a low degree of hygroscopicity. Therefore, as described above, using the Cat-CVD film as the top layer passivation film makes it possible to improve the anti-moisture property of the semiconductor device.

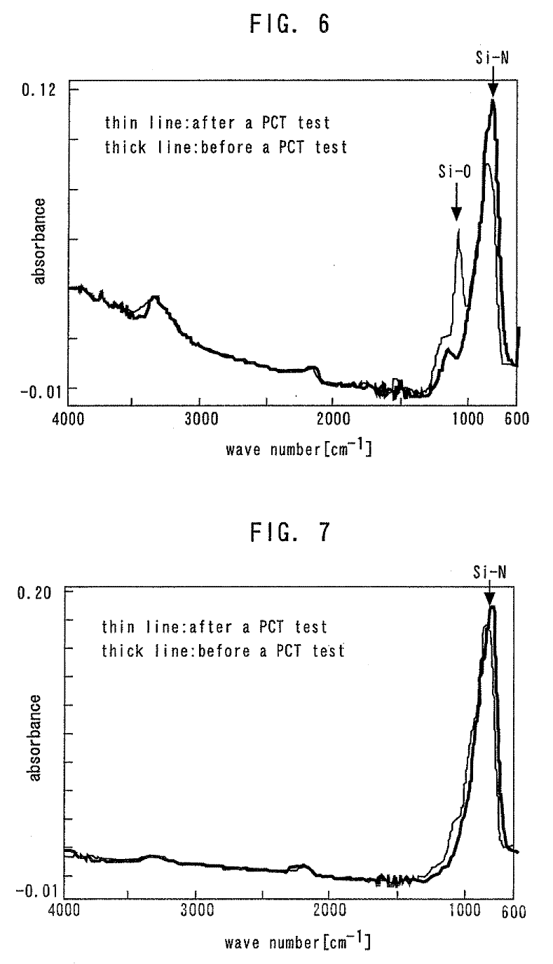

FIG. 6 shows a spectrum of a semiconductor device using a P-CVD film measured using an FTIR (Fourier Transform Infrared Spectrometer) before and after a PCT test (pressure cooker test) and FIG. 7 shows a spectrum of a semiconductor device using a Cat-CVD film measured using an FTIR before and after a PCT test. Test conditions for the PCT test are 121° C., 2 atmospheres and 96 hours.

It is appreciated from this measurement result that, when the P-CVD film is used, a peak of Si-O is observed after the PCT test but when the Cat-CVD film is used, substantially no peak of Si—O is observed after the PCT test. Furthermore, it is also appreciated that when the P-CVD film is used, the peak height of Si—N decreases after the PCT test compared to before the PCT test, but when the Cat-CVD film is used, the amount of decrease in the peak height of Si—N before and after the PCT test is small.

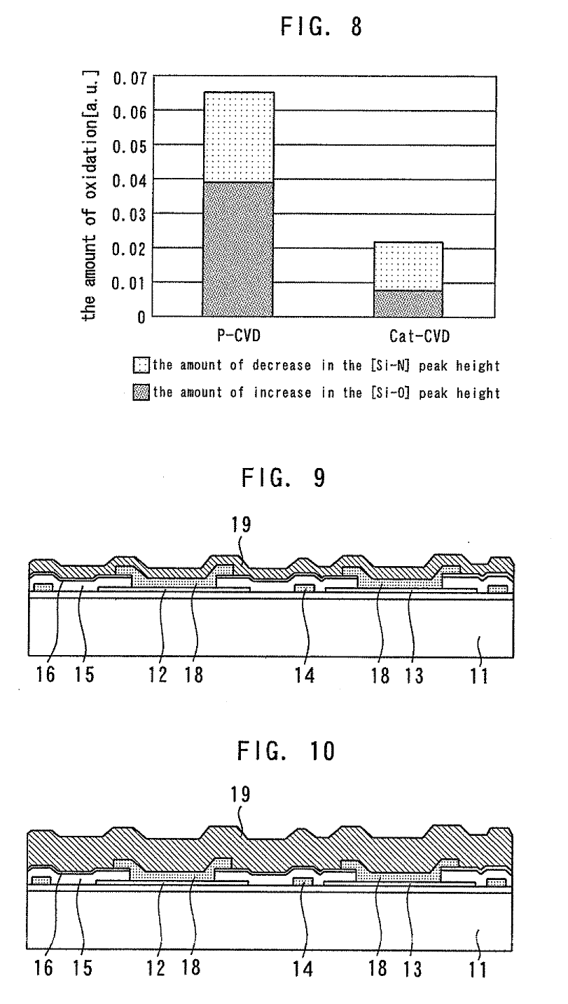

FIG. 8 shows the amount of oxidation measured after a PCT test on a semiconductor device using a P-CVD film and a semiconductor device using a Cat-CVD film. Here, the sum of the amount of decrease in the [Si—N] peak height and the amount of increase in the [Si—O] peak height of a spectrum measured using an FTIR after the PCT test is defined as the amount of oxidation. It is appreciated from this measurement result that using the Cat-CVD film can drastically reduce the amount of oxidation compared to using the P-CVD film. Therefore, it could be confirmed through an experiment that use of this Embodiment can improve the anti-moisture property.

### Second Embodiment

FIG. 9 is a cross-sectional view showing a semiconductor device according to Second Embodiment of the present invention. In this Embodiment, the film thickness of a SiN film 19 formed using a catalytic chemical vapor deposition method is 1000 Å. The rest of the configuration and the manufacturing method are the same as those of First Embodiment.

The Cat-CVD film can obtain an equivalent anti-moisture property with a film thickness approximately ⅓ of that of the P-CVD film. Therefore, the film thickness of the SiN film 19 can be reduced to 1000 Å or below. In this way, it is possible to improve film formation throughput, reduce material cost and realize a capacity reduction.

### Third Embodiment

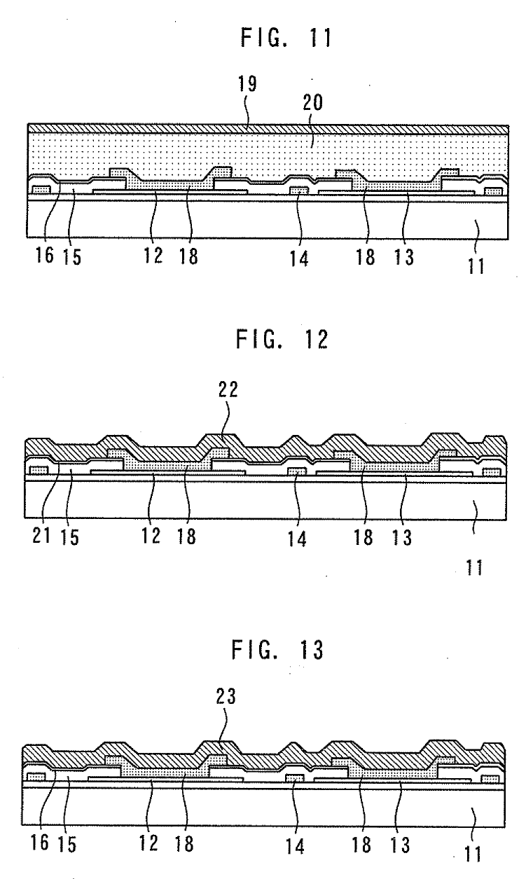

FIG. 10 is a cross-sectional view showing a semiconductor device according to Third Embodiment of the present invention. In this Embodiment, the film thickness of a SiN film 19 formed using a catalytic chemical vapor deposition method is 10000 Å. The rest of the configuration and the manufacturing method are the same as those of First Embodiment.

Stress of the Cat-CVD film is 1×10⁹ dyn/cm² and is smaller than stress of 1×10¹⁰ dyn/cm² of the P-CVD film. Therefore, the film thickness of the SiN film 19 can be made 10000 Å or more and this allows the anti-moisture property to be improved.

### Fourth Embodiment

FIG. 11 is a cross-sectional view showing a semiconductor device according to Fourth Embodiment of the present invention. A thick, low dielectric constant film 20 is formed on passivation films 15, 16. A SiN film 19 of 1000 Å is formed on this thick, low dielectric constant film 20 using a catalytic chemical vapor deposition method. The rest of the configuration and the manufacturing method are the same as those of First Embodiment.

In this way, planarization using the thick, low dielectric constant film 20 before forming the SiN film 19 eliminates influences of coverage by the SiN film 19 on stepped parts, and can thereby further improve the anti-moisture property. However, the thick, low dielectric constant film 20 is preferably planarized before forming the SiN film 19 using CMP (Chemical Mechanical Polishing).

As the thick, low dielectric constant film 20, any one or a combination of polyimide, BCB, PAE (Poly Arylene Ether), HSQ (Hydrogen Silse Quioxane), MSQ (Methyl Silse Quioxane), SiOC and SiOF may be used.

### Fifth Embodiment

FIG. 12 is a cross-sectional view showing a semiconductor device according to Fifth Embodiment of the present invention. A SiN film 21 of 500 Å (second passivation film) is formed on a passivation film 15 (first passivation film) using a catalytic chemical vapor deposition method. A SiN film 22 of 3000 Å (third passivation film) is formed on the SiN film 21 using a catalytic chemical vapor deposition method. The rest of the configuration and the manufacturing method are the same as those of First Embodiment.

In this Embodiment, an intermediate passivation film, which is not the top layer and has no contact with semiconductor, is formed using a catalytic chemical vapor deposition method. In this way, the anti-moisture property can be improved as in the case of First Embodiment. The film thickness of the SiN film 21 which is the intermediate passivation film is preferably set to 1000 Å or less.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2007-143890, filed on May 30, 2007 including specification, claims, drawings and summary, on which the Convention priority of the present application is based, are incorporated herein by reference in its entirety.

1. A semiconductor device comprising:
a semiconductor substrate;
a first passivation film which covers a top surface of the semiconductor substrate; and
a second passivation film formed on the first passivation film by catalytic chemical vapor deposition.

2. The semiconductor device according to claim 1, wherein the second passivation film is a SiN film.

3. The semiconductor device according to claim 1, wherein the second passivation film is a top layer passivation film.

4. The semiconductor device according to claim 3, wherein the second passivation film has a thickness not exceeding 1000 Å.

5. The semiconductor device according to claim 3, wherein the second passivation film has a thickness of at least 10000 Å.

6. The semiconductor device according to claim 1, further comprising a thick, low dielectric constant film on the first passivation film, wherein the second passivation film is on the thick, low dielectric constant film.

7. The semiconductor device according to claim 6, wherein the thick, low dielectric constant film is any one or a combination of polyimide, BCB, PAE (Poly Arylene Ether), HSQ (Hydrogen Silse Quioxane), MSQ (Methyl Silse Quioxane), SiOC, and SiOF.

8. The semiconductor device according to claim 6, wherein the thick, low dielectric constant film is planarized by (Chemical Mechanical Polishing).

9. The semiconductor device according to claim 1, further comprising a third passivation film on the second passivation film.

10. The semiconductor device according to claim 9, wherein the second passivation film has a thickness not exceeding 1000 Å.
